(19) United States
(12) Patent Application Publication
(10) Pub. No.: US 2021/0074873 A1
(43) Pub. Date: Mar. 11, 2021

(54) METHOD FOR CONFIGURING A MULTILAYER SPECTRAL-SEPARATION FILTER FOR PHOTOVOLTAIC AND THERMAL USES AND FILTER AND GENERATION PLANT ASSOCIATED WITH SAID METHOD

(71) Applicant: BLUESOLAR FILTERS S.L, Sevilla (ES)

(72) Inventor: Sebastián CAPARROS JIMENEZ, Sevilla (ES)

(73) Assignee: BLUESOLAR FILTERS S.L, Sevilla (ES)

(21) Appl. No.: 16/955,713

(22) PCT Filed: Nov. 28, 2018
(86) PCT No.: PCT/ES2018/070762

§ 371 Date: Jun. 18, 2020

(30) Foreign Application Priority Data
Jan. 3, 2018 (ES) P201830001

(51) Int. Cl. H01L 31/054; H01L 31/18

(52) U.S. Cl. CPC H01L 31/0549; H01L 31/18

(57) ABSTRACT

A selective multilayer filter is configured for spectral separation of solar radiation. The filter is suitable to be disposed on photovoltaic panels for use in energy generation plants. The multilayer filter includes layers of different refractive indices and thicknesses. A method for configuring the selective multilayer filter for spectral separation of solar radiation includes performing a series of steps to configure multilayer filter such that photovoltaic and thermal efficiency is maximized. Also disclosed are the multilayer filter configured using the method and a plant for generating energy by harnessing solar energy, using at least one multilayer filter configured using the method.

### SCOPE OF THE INVENTION

This invention refers to a method for configuring a multilayer spectral-separation filter for solar radiation to transmit said radiation to a photovoltaic (PV) cell in the ranges in which it is more efficient than a thermal receiver, such as a concentration solar power (CSP) plant and, to reflect said radiation to a thermal receiver the ranges of solar radiation in which it is more efficient than the photovoltaic cell. The main sector within which the invention is included is, therefore, that of selective treatment of solar radiation to be used in thermal and electrical energy systems of industrial plants.

### BACKGROUND OF THE INVENTION

Within the field pertaining to solar energy generation technologies, two main groups can be distinguished: solar thermal concentration technology and solar photovoltaic generation technology. The operating principle of both is substantially different, each having its own advantages and disadvantages. Solar thermal energy is based on the use of optical components, usually mirrors, to generate concentrated light that is used to heat-up a heat transfer fluid. Said superheated fluid is used as input in a traditional turbine cycle, to heat another fluid which is the fluid that enters into said cycle. For its part, photovoltaic solar power is characterised by the use of semiconductors, mainly made from crystalline silicon, which generate direct electricity after absorbing the solar radiation via photoelectric effect.

Solar thermal energy has the great advantage that, given that it is based on fluids that act as a heating medium, they can be stored in tanks and introduced into the turbine cycle at the required time of day, or even at night. This means that solar thermal energy has the competitive advantage that it is energy that can be stored for later use. As a major disadvantage, said energy is significantly more complex to handle than solar photovoltaic energy and other conventional sources, making it more expensive to generate electricity by this means than by other sources.

Solar photovoltaic energy is, however, considerably simpler and its costs are lower than those of solar thermal power, being comparable to that of conventional sources. The great disadvantage that it presents is that, as it is a direct generation of electricity, its storage is not feasible unless batteries are used, which requires high equipment and maintenance costs. Therefore, photovoltaic energy does not enable, in practice, large-scale storage in commercial plants, which implies that the delivery of energy to the grid is not synchronised with the actual demand that may exist in said grid.

Within the area of solar thermal systems, the two technologies that currently dominate the market are the parabolic trough and the tower. In those with a parabolic trough, a conduit or tube with the fluid to be heated circulates through the focus region of one or more parabolic mirrors, which concentrate solar radiation within said conduit. In tower technology, a solar field of mirrors concentrates the radiation in a concentration region located within the tower, in which the receiver where the heat transfer fluid circulates is installed.

Parabolic trough technology is the most mature and has been the dominant technology throughout the historical development of solar thermal energy. However, recently, solar thermal towers have been prevailing, given that they have, amongst other things, the advantage that the concentration of light is more effective than in the parabolic trough and, therefore, higher temperatures can be reached and the efficiency of thermodynamic cycles can be increased. Furthermore, the circulation of heat transfer fluids is limited to the central area of the plant where the tower is located, whilst in the parabolic cylinder, being a linear system, the tubes extend entirely throughout the plant, which greatly increases its complexity. Therefore, currently, solar thermal towers have lower generation costs than the parabolic trough and are undoubtedly the future of this type of technology.

In relation to photovoltaic technology, the clearly dominant technology is that of mono- or polycrystalline silicon. These are simple systems with great economies of scale and, therefore, very cheap and which can compete in cost with conventional generation sources.

Also, the use of selective light filters is known for certain solar applications, such as those described in patent applications JP 2009218383 and US 20150083194, in which thermo-solar tower systems are described in which heliostats would be composed of photovoltaic modules. These photovoltaic modules have built-in dielectric mirrors of the “hot-mirror” type or infrared reflective films that are used as part of the elements intended to redirect sunlight to the central receiver of the tower.

These systems, however, do not currently have real commercial application given that hot-mirrors or infrared reflective films, even though they are elements that are capable of being included in reflective or collecting surfaces, present a series of disadvantages and disadvantages that prevent their use on a large scale. The reason for which these elements are not valid in the aforementioned commercial applications is explained in detail below:
Infrared reflective films comprise a deposition of materials on a polymeric layer that subsequently adheres to the glass of the photovoltaic modules. This product configuration is not valid in commercial applications. Given that the film is exposed to external environmental conditions, it suffers a lot of degradation due to the abrasion of the environmental conditions of the area. Furthermore, such films do not guarantee specular reflection that is needed to ensure the reflected radiation is able to reach the receiver of the tower.
Hot-mirrors comprise a deposition of dielectric materials to reflect infrared light and allow the passage of visible light. They are usually designed by selected a cut-off wavelength, typically 700-750 nm and by introducing periodic material designs to achieve very high reflectances from that cut-off wavelength. A hot-mirror is not an optimal material specification for a photovoltaic-solar thermal application, for the following reasons:
   Infrared light starts from 700-750 nm. FIG. 1 of this document shows the typical transmission curve of a hot-mirror. However, a silicon photovoltaic cell has its maximum efficiency peaks precisely in that range in which the hot-mirror would begin to reflect light, as can be seen in FIG. 2, which shows the quantum efficiency of commercial silicon cells. Therefore, a very important useful significant would be subtracted from the photovoltaic cell, which drastically reduces its performance.
   As mentioned, a hot-mirror seeks a maximum spectrum reflectance from approximately 700-750 nm, which is achieved by making periodic designs based on oxide thicknesses of the quarter wavelength of the range to be reflected, involving a high number of layers. A high number of layers greatly increases the price, the difficulty and the time of the deposition and makes its use unfeasible in these applications, in which the cost and the number of layers is a fundamental limiting factor.
   In solar applications that make use of the solar spectrum, there are infrared areas in which no radiation is received, given that there are absorption peaks of water vapour. A hot-mirror would be reflecting indiscriminately in those wavelength ranges, which does not make sense given that radiation is not received, therefore it would be reflecting 100% of nothing. Those infrared reflectance zones where no radiation is received adds an unnecessary cost to the system and is further proof that they are not solutions intended for solar applications.
   A hot-mirror transmits the entire visible area, including the blue area, being transparent to the human eye. An optimal photovoltaic-solar thermal application should have a material that reflects blue, given that, at these wavelengths, the quantum efficiency of silicon cells decreases and it is more efficient to reflect radiation to the thermal receiver.

Related to these stated needs, patent applications are known, such as application WO 2015117134 A1, in which parabolic trough collector systems with spectral-separation systems are proposed, in which there is, again, a lack of detail in the design claim of selective filters and obvious questions regarding spectral light separation are generically specified.

In general, the traditional criteria for designing filters has been essentially based on introducing thicknesses of a quarter of the wavelength intended to be reflected. Essentially, the usual method is to select the wavelength intended to be reflected and to calculate the thickness of the materials according to the following expressions:

$$\begin{matrix}{T}_{H} = \frac{{λ}_{0}}{4 {n}_{H}} & ( Eq . a ) \\ {T}_{L} = \frac{{λ}_{0}}{4 {n}_{L}} & ( Eq . b )\end{matrix}$$

Where T is the thicknesses, λ₀ is the wavelength that is intended to have a maximum peak of reflectance and n is the refractive indices. The reflectance width is set by the index contrast and the intensity of the reflection is controlled by adding the torque with the same thicknesses n times, until the desired peak is achieved. To extend the range of reflection, it would be necessary to take another pair of thicknesses and repeat it n times.

This design criterion for interference filters are those used in traditional optics and are those that, even without being specifically detailed in the patents related to solar plants, are shown to be used, when naming concepts such as hot-mirrors or heat-reflective films, given that these components are based on these designs and also have transmission curves identical to those that can be achieved with periodic designs.

Therefore, mainly due to the fact that the state of the art of interference filters based on traditional optics is not adapted to solar applications and is based on periodic designs, very inefficient and very expensive solutions are obtained, which present a certain degree of difficulty in their manufacture. Therefore, it is not surprising that none of the systems claimed in the aforementioned patents have found commercial application.

As an alternative to the solutions detailed above, selective sunlight filters deposited on glass as a substrate are also known, such as those described in patent application ES 2636800 A1. In this type of filters, which comprise periodically alternating layers of high and low refractive index, the incident light undergoes selective reflection to allow a majority of wavelengths to pass to a photovoltaic cell and to reflect a majority of wavelengths towards a thermal receiver. However, these filters are far from being an optimal solution for their commercial application, given that there are wavelengths that are reflected towards the thermal receiver where the semiconductors of the photovoltaic cells are still highly efficient and, therefore, are not the most efficient overall solution for a selective filter located in a hybrid solar field consisting of photovoltaic (PV) modules and a central receiver solar thermal power plant (CPS). This set of wavelengths that are no longer used in these periodic filters is blocked by the difficulty in configuring a suitable, more efficient, filter.

Due to all of the above, there is still a need to provide a selective light filter that is easy to configure and manufacture, with a low number of layers, that allows for the wavelength selection of incident sunlight with high efficiency to be adjusted, surpassing the known solutions of the state of the art; and which, as an added value, is uncomplicated and low cost. Achieving a simple, highly efficient solar filter with a low number of layers would reduce the complexity of manufacturing and repairing the filters in solar plants, given that it would require less time for the deposition of the layers and, additionally, the smaller amount of material, the simpler and cheaper it would be to replace or repair them.

This invention proposes a solution to this technical problem posed through a method for configuring a multilayer selective light filter that enables the difficulties mentioned above to be overcome, through the configuration of a highly efficient aperiodic multilayer filter within a range of desired wavelengths with low number of layers.

### BRIEF DESCRIPTION OF THE INVENTION

One aim of this invention refers, albeit without limitation, to the development of a method for configuring a multilayer spectral-separation filter for solar radiation, suitable for placement on photovoltaic panels for use in power generation plants, for using solar energy, where the multilayer filter comprises multiple layers with different refractive indices and thicknesses.

Advantageously, said method involves the performance of the following steps to configure said multilayer filter in terms of a desired transmittance and reflectance within a range of wavelengths:

a) defining a first initial filter with a number of layers and refractive indices of known layers, with a random thickness of each layer;
b) the transmittance and reflectance response of said initial filter within the desired wavelength range is calculated according to the optical admittance of the initial filter and the optical admittance of the medium;
c) the photovoltaic efficiency of said initial filter is calculated according to the transmittance and reflectance calculated in step b) within the desired wavelength range; where:
the photovoltaic efficiency is calculated by multiplying the performance ratio or standard performance ratio of a photovoltaic plant by the efficiency of the photovoltaic cell according to its spectral response; and
the efficiency of the photovoltaic cell is defined in terms of the cell's current density, global radiation, the cell's open-circuit voltage and fill factor;
   d) the thermal efficiency of said initial filter is calculated according to the transmittance and reflectance calculated in step b) within the desired wavelength range; where:
thermal efficiency is calculated by multiplying the average annual efficiency of a concentrated solar thermal power plant by the ratio of direct radiation versus direct radiation added to diffuse radiation, by the integrated reflectance of the initial filter for the desired wavelength range; and
the average annual efficiency of a concentrated solar power plant is calculated by multiplying the factors: efficiency of the solar field, efficiency of the turbine power cycle and the loss of efficiency of the plant due to the self-consumption of equipment;
   e) a merit function is calculated and recorded, calculated as the sum of the photovoltaic and thermal efficiencies resulting from steps c) and d);
   f) a set of initial filters is defined with the same number of layers as the first initial filter but with different thicknesses for the layers of each of said filters with respect to the first initial filter and steps b) to e) are repeated for each of said filters;
   g) the optimal multilayer filter is chosen, belonging to the set of filters from step f) plus the first initial filter, where said optimal multilayer filter comprises the combination of thicknesses that maximises the merit function for a given number of layers, from all merit functions calculated in step e).

This is achieved by providing a tool for configuring an aperiodic multilayer filter that is highly efficient within the desired wavelength range. It is especially possible to configure a solar filter that reflects the least efficient wavelengths at the photovoltaic level and that transmits the most efficient wavelengths, maximising efficiency and, furthermore, depending on the type of semiconductor used for the photovoltaic conversion, the filter can be redesigned. Additionally, it can be redesigned under other technical criteria, still maximising efficiency.

In a preferred embodiment of the invention, the method for configuring a selective multilayer spectral-separation filter for solar radiation further involves an additional step, in which a set of secondary filters is defined. Each of those filters with a different number of layers between them, as well as a different number of layers from the first initial filter, with known refractive indices and with a random thickness of each layer; steps b) to g) are repeated to obtain an optimal multilayer filter from the secondary filter set for each given number of layers.

This is achieved by providing a set of optimal filter solutions for each given number of filter layers.

Preferably, the method of the invention further includes an additional step, where:
a desired critical merit function is established;
a desired critical number of layers is established;
a final optimum filter is selected from all of the registered optimal filters in such a way that said final optimal filter is that which most closely approximates the established criteria of said critical merit function and said critical number of layers.

This makes it possible to choose an optimal filter that has a certain number of layers, such as, for example, a low number of layers, to simplify manufacturing. In this way, it is also possible to choose minimum criteria for total filter efficiency, or to reach a compromise between the number of layers and the total efficiency. Optionally, these criteria can be modified and new criteria can be established, according to the needs of the specific filter.

In a preferred embodiment of the invention, in step b) of the method of the invention, the transmittance and reflectance response of said initial filter within the desired wavelength range is calculated through the calculation of at least the following parameters:
the characteristic matrix of a multilayer system;
the phase term according to the wavelength, layer thickness and angle of incidence;
the complex refractive index of a multilayer system;
the optical admittance of a substrate on which a multilayer deposition is carried out to construct the multilayer filter.

In a preferred embodiment of the invention, in step c) of the method of the invention, the current density is calculated from the wavelength, the quantum efficiency of the cell, the charge of the electron, the Planck constant and the speed of light.

Another aim of the invention relates to a selective multilayer spectral-separation filter for solar radiation, suitable for maximising the efficiency of a photovoltaic and concentrated solar thermal power system, configured through a method of configuration according to any of the previous embodiments. Preferably, said multilayer filter comprises layers in aperiodic structure. More preferably, said multilayer filter is dichroic.

With this, the range of configurations of the selective light filters is greatly expanded with respect to the state of the art, given that their configuration is not restricted to a periodic design. Therefore, with an aperiodic filter, it is possible to cause reflections of different wavelengths in each layer, which increase the possible combinations resulting in the reflections, not being restricted to Fabry-Perot reflections or to those reflections resulting from the sum of reflections of a periodic structure of known layers.

The invention also enables an ad-hoc filter to be provided for according to the specific needs that are required to select certain ranges of wavelengths and transmit or reflect in a subset of those wavelengths, also offering a range of solutions for the same conditions.

More preferably, the multilayer filter comprises transparent oxides of high and low refractive index. Even more preferably, the multilayer filter comprises titanium oxide and silicon oxide or any compound derived therefrom. Yet more preferably, the silicon oxide and titanium oxide layers have thicknesses of between 5 and 500 nm.

In a preferred embodiment of the multilayer filter, the latter is configured in such a way that the wavelength ranges with minimum reflection in said aperiodic structure correspond to wavelength ranges with maximum absorption in the terrestrial solar spectrum. This is achieved by providing a filter designed for use in solar power plants comprising photovoltaic cells and comprising a thermal receiver.

In a preferred embodiment of the multilayer filter, the filter comprises a glass substrate. The deposition of the layers on the glass substrate is preferably carried out by means of the sputtering technique.

In a preferred embodiment of the multilayer filter, the filter comprises between 3 and 20 layers. Preferably, the filter comprises between 3 and 10 layers. More preferably, the filter comprises between 5 and 7 layers.

Another aim of the invention refers to a power generation plant by harnessing solar energy that comprises the use of at least one multilayer filter configured via a configuration method according to the previous embodiments, in which at least one multilayer filter is configured to let solar radiation of visible wavelengths pass into a corresponding photovoltaic cell and to reflect solar radiation of shorter and longer wavelengths with respect to visible radiation to a central receiver.

In this way, this invention provides a solution that overcomes the problems of the state of the art, enabling the configuration of a multilayer filter specifically designed to have a high efficiency and a low number of layers, which greatly simplifies the manufacturing process and opens a door to the industrial manufacturing and marketing of these selective sunlight filters for implantation in hybrid photovoltaic and solar thermal plants.

### DESCRIPTION OF THE FIGURES

FIG. 1 shows the transmission curve of a standard hot-mirror.

FIG. 2 shows the typical quantum efficiency of silicon photovoltaic cells.

FIG. 3 shows a diagram of a longitudinal section of an aperiodic filter and a diagram of its optical operation, according to a preferred embodiment of the invention.

FIG. 4 shows both the transmittance curve and the reflectance curve of a selective light filter with a 7-layer aperiodic structure that maximises the photovoltaic and solar thermal concentration (PV-CSP) efficiency, configured by the method of the invention, according to a preferred embodiment thereof.

FIG. 5 shows a diagram of a power generation plant using solar energy that comprises a photovoltaic cell and a thermal central receiver, as described in this invention.

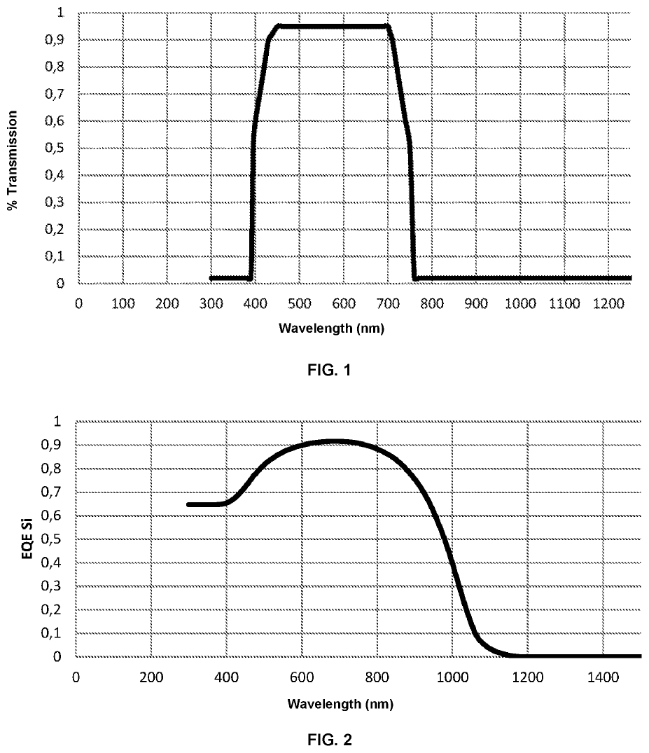

### NUMERICAL REFERENCES USED IN THE FIGURES

In order to aid a better understanding of the technical characteristics of the invention, the Figures are accompanied by a series of numerical references where, by way of example and by no means exhaustive, the following is shown:

| | |
|---|---|
| (1) | Multi-layer filter |
| (2) | Filter layers |
| (2′) | Interfaces |
| (3) | Filter substrate |
| (4) | Photovoltaic cell or PV cell |
| (5) | Thermal central receiver or concentrated |
| | solar thermal power (CSP) plant receiver |
| 100 | Incident beam |
| 101 | Resulting reflected beam |
| 102 | Parts reflected in the interfaces |
| 104 | Part of the light transmitted by the filter |

### DETAILED DESCRIPTION OF THE INVENTION

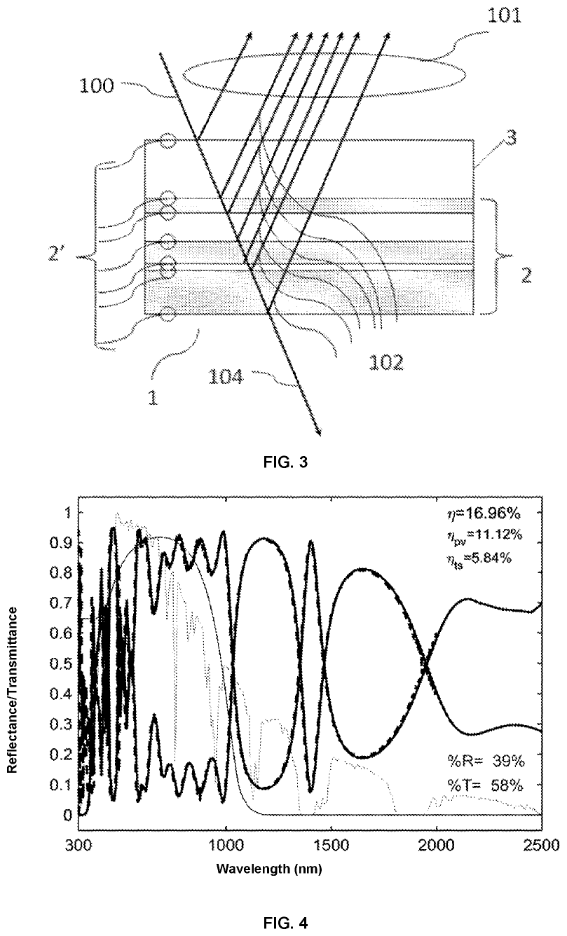

Below is a detailed description of the method and filter of the invention, referring to a preferred embodiment thereof, based on FIGS. 3-5 of this document. Said embodiment is provided for by way of example, but by no means exhaustive, purposes of the claimed invention.

One object of the invention relates to a method for configuring a selective sunlight multilayer filter (1) (FIG. 3), preferably comprising transparent oxides (in a wavelength range of interest), with a high and low index of refraction, alternated, in an aperiodic configuration as regards its thickness in the layer structure (2) and deposited directly onto a glass substrate (3). The method of the invention therefore focuses on configuring a filter (1) which comprises a low number of layers (2) and which is optimal for:
transmitting sunlight in its path to a photovoltaic (PV) cell (4), located adjacent to the filter (1), at the wavelengths in which the photovoltaic cell (4) is more efficient in terms of absorbing solar energy to transform it into electrical energy;
reflecting the sunlight that reaches the filter (1) in the wavelengths in which the photovoltaic cell (4) is less efficient in terms of absorbing solar energy to transform it into electricity; and, at the same time, collecting the sunlight reflected in a thermal receiver (5), such as, for example, a concentrated solar thermal power (CSP) plant (5).

In the method for configuring the multilayer filter (1) of the invention, the known electromagnetic theory and general knowledge of solid-state physics, applied to multilayer systems such as the filter (1), to photovoltaic (PV) cells (4) adjacent to said multilayer systems, as well as photovoltaic cell (4) solar power plants and concentrated solar thermal power (CSP) plants (5) are used.

The method of the invention comprises four fundamental stages: defining an initial filter, calculating the filter response; optimising the thickness of the layers (2) for a determined number of layers (2) and optimising the number of layers (2). Each of the stages is described in detail below.

### 1.—Defining an Initial Filter

The method requires base data, prior to optimising the multilayer filter (1). Firstly, an initial filter, j, is defined. It is assumed that said initial filter, j, is manufactured by layer-by-layer (2) deposition on a known substrate (3), for which it is necessary to choose a number, L, of layers (2) with a known random thickness:

tᵢⱼ={tᵢⱼ}={t₁ⱼ,t₂ⱼ, . . . ,t_{Lj}} (Eq. 1.1)

Where i=1, . . . , L and tᵢⱼ is the random initial thickness of layer (2) i of initial filter j. Each layer (2) has a known complex refractive index Nᵢ, within a determined wavelength range:

Nᵢ={Nᵢ}={N₁,N₂, . . . ,N_{L}} (Eq. 1.2)

### 2.—Calculating the Initial Filter Response

Secondly, the response of the initial filter, j, when solar radiation reaches it, must be calculated. For this, a range of wavelengths, λ, is defined within which the multilayer filter (1) is to be optimised.

Subsequently, the response of the initial filter, j, which is light selective, defined by the following equations, is calculated:

$$\begin{matrix}{δ}_{L} = \frac{2 π {N}_{L} {t}_{L}}{λ} cos ( {θ}_{L} ) & ( Eq . 2.1 ) \\ {N}_{L} = {n}_{L} - i {k}_{L} & ( Eq . 2.2 ) \\ {η}_{S} = \frac{{H}_{S}}{{E}_{S}} & ( Eq . 2.3 ) \\ ( \begin{matrix}{E}_{A} \\ {H}_{A}\end{matrix} ) = \{ {Π}_{L = 1}^{n} ( \begin{matrix}cos {δ}_{L} & ( i sin {δ}_{L} ) \text{/} {η}_{L} \\ i {η}_{L} sin {δ}_{L} & cos {δ}_{L}\end{matrix} ) \} [ \begin{matrix}1 \\ {η}_{S}\end{matrix} ] & ( Eq . 2.4 )\end{matrix}$$

where:
Eq. 2.4 is the characteristic matrix of a multilayer system that defines the optical response of the initial filter, j, where L refers to the layer number (2);
δ_{L} is the phase term of layer L, λ is the wavelength, t_{L} is the thickness of layer L of the initial filter j and θ_{L} is the angle of incidence of the radiation with respect to the multilayer system;
N_{L} is the complex refractive index, where n_{L} is the refractive index and k_{L} is the extinction coefficient; both previously known.
ηₛ is the optical admittance of the substrate (3) on which the deposition of the layers (2) is carried out, which is known.
E_{A} is the intensity of the electric field.
H_{A} is the intensity of the magnetic field.

By resolving Eq. 2.4 through all the known parameters, one reaches the resolution coefficients p₁₁, p₁₂, p₂₁, p₂₂, of the characteristic matrix:

$$[ \begin{matrix}{p}_{11} & {p}_{12} \\ {p}_{21} & {p}_{22}\end{matrix} ] \qquad ( Eq . 2.5 )$$

Given that the optical admittance of the multilayer is defined by:

$$Y = \frac{{H}_{A}}{{E}_{A}} = \frac{{p}_{21} + {p}_{22} {η}_{S}}{{p}_{11} + {p}_{12} {η}_{S}} \qquad ( Eq . 2.6 )$$

The complex reflection coefficient can be calculated according to the following equations:

$$r = \frac{{η}_{A} - Y}{{η}_{A} + Y} \qquad ( Eq . 2.7 )$$

η_{A}(s polarisation)=N_{A} cos(θ_{A}) (Eq. 2.8)

η_{A}(p polarisation)=N_{A}/cos(θ_{A}) (Eq. 2.9)

Where η_{A} is the optical admittance of the medium (air, in this case) and is defined by Eq. 2.8 and 2.9, depending on whether the polarisation of light is s or p.

Lastly, the total transmittance and reflectance of the initial multilayer or filter j is calculated according to the wavelength:

R(Δ)=r×r (Eq. 2.10)

T(λ)=1−R(λ) (Eq. 2.11)

In this way, for the initial filter j with known parameters, its spectral response is characterised for a determined wavelength. This calculation can thus be applied to a discretised wavelength range of interest. Specifically, for all wavelengths in the solar spectrum, the response of the initial filter j can be calculated.

Once the spectral response of the initial filter j has been characterised for all wavelengths, the total efficiency of the initial filter j, Ef_{total j}, can be calculated in terms according to a merit with a component of photovoltaic (PV) efficiency, Ef_{PV} and another thermal (CSP) efficiency component, Ef_{CSP}:

(Ef_{total j}=Ef_{PV j}+Ef_{CSP j}→)Efₜₒₜₐₗ=Ef_{PV}+Ef_{CSP} (Eq. 2.12)

To calculate the photovoltaic efficiency, Ef_{PV}, of the initial filter j, the following expressions are used:

Ef_{PV}=Ef_{cel}×PR (Eq. 2.13)

### Where:

PR is the typical performance ratio of photovoltaic (PV) plants, which typically has a value of around 0.8; where the losses of efficiency by cosine factor are taken into account (de-targeting with respect to the normal cosine factor of the sun); shading losses; spectral losses; losses due to irradiation; temperature losses; mismatch losses; wiring losses; losses due to the operation of the inverter, inverter efficiency losses due to operating outside the nominal point; inverter losses due to receiving power outside of its working limit; inverter losses due to voltage within its operating range; inverter losses due to receiving voltage outside its operating limit; losses due to consumption of equipment during the night; losses due to self-consumption of auxiliary equipment; losses in AC and losses due to the transformer station:

PR=η_{cos}×η_{shade}×η_{IAM}×η_{dirt}×η_{irrad}×η_{T}×η_{missmatch}×η_{wiring}×η_{inverter op}×η_{inverter nominal}×η_{inverter limit}×η_{inverter voltage}×η_{inverter limit voltage}×η_{night consumption}×η_{auxiliary equipment}×η_{AC Ohmix}×η_{Transformer} (Eq. 2.14)
Ef_{cel} is the efficiency of the photovoltaic cell according to its spectral response, which, in simple models, is usually defined by the following expression:

$${Ef}_{cel} = \frac{{J}_{sc} \times {V}_{oc} \times FF}{GNI} \qquad ( Eq . 2.15 )$$

Where J_{sc} is the current density of the photovoltaic cell, GNI is the global radiation (direct radiation plus diffuse radiation), V_{oc} is the open circuit voltage of the cell and FF is the characteristic filling factor. J_{sc}, the current density of the photovoltaic cell, depends on the spectrum and is, in turn, defined by the following expressions in simple models:

J_{sc}=Σ_{λ}J_{sc}(λ) (Eq. 2.16)

Jsc(λ)=λ×GNI(λ)×EQE×Transmission_{filter}(λ)×a/hxc (Eq. 2.17)
Where λ is the wavelength, GNI is the global radiation, EQE is the quantum efficiency of the photovoltaic cell, q is the charge of the electron, h is the Planck constant and c is the speed of light and Transmission_{filter} is the integrated transmission of the filter for the solar spectrum to be optimised.
By integrating Jsc throughout the entire solar spectrum with the help of Eq. 2.16 and 2.17 and by calculating the typical PR of a photovoltaic plant as in Eq. 2.14, the calculation of the photovoltaic efficiency of the initial filter j via Eq 2.13: Ef_{PV j} is complete:

Similarly, to calculate the solar thermal efficiency of the initial filter j, Ef_{CSP j}, the following expression is used:

Ef_{CSP}=Ef_{Av}×DNI/GNI×Reflectance_{filter} (Eq. 2.18)

where:
Ef_{Av} is the annual average efficiency of a concentrated solar power (CSP) plant, normally between 15-20% depending on the type of plant. That is typically calculated through the following expression (Eq. 2.19) in which the factors that are multiplied for the calculation are the efficiency of the solar field, the efficiency of the turbine power cycle and the loss of efficiency of the plant due to self-consumption of equipment:

Efₐᵥ=η_{solar field}×η_{power cycle}×η_{self-consumption} (Eq. 2.19)
The efficiency of the solar field would be calculated according to the following expression:

η_{solar field}=η_{cos}×η_{shadows}×ηₐₜₜₑₙᵤₐₜᵢₒₙ×η_{blockages}××η_{overflow}×η_{thermal receiver}×η_{damping} (Eq. 2.20)
Where the multiplicative factors of Eq. 2.20 represent the following concepts: efficiency by cosine factor (de-targeting with respect to the normal cosine factor of the sun); shadows between adjacent collectors; energy losses due to atmospheric attenuation; blockages (reflected energy that does not reach the thermal receiver due to its impact on adjacent collectors); overflow losses (reflected light that is not blocked does not hit the heat sink as the sensors are out of alignment or working outside of their allowable tolerance range); loss of light-thermal energy conversion in the receiver and, lastly, energy that is not introduced into the receiver as it does not accept more thermal load and the collectors are completely de-targeted.
DNI/GNI is the ratio of direct radiation vs. global radiation.
Reflectance_{filter} is the integrated reflectance of the multilayer filter for the solar spectrum to be optimised, which is typically calculated using the following expression:

$${Reflectance}_{filter} = \frac{{\sum }_{λ} λ \times DNI ( λ ) \times R ( λ )}{DNI} \qquad ( Eq . 2.20 )$$

In this way, for the initial filter j, a merit function Ef_{total j} can be obtained according to Eq. 2.12 and with the help of the set of expressions Eq. 2.1-2.11 and Eq. 2.13-2.20. This merit function calculated for the initial filter j is recorded at this stage.

### 3.—Optimising the Thickness of the Layers (2) for a Determined Number of Layers (2)

In the next step, a set of initial filters, j=2, . . . , J is defined, with the same number L of layers (2) as the first initial filter, j=1, but with different random thicknesses for the L layers (2):

tᵢⱼ={tᵢⱼ}={tᵢ₁,tᵢ₂, . . . ,tᵢⱼ} (Eq. 3.1)

In this way, each {tᵢⱼ} is a different set of random thicknesses for a given number L of layers (2), where there are J sets of random thicknesses, one for each initial filter j: {tᵢ₁}, {tᵢ₂}, . . . , {tᵢⱼ}.

For each of these initial filters j, with their thickness {tᵢⱼ}, all the calculations from the previous step are repeated; that is, the initial filter response is calculated using the equations Eq. 2.1-2.20, recording all the resulting merit functions, obtaining a set of J merit functions: {Ef_{total j}} with j=1, . . . , J.

Subsequently, the optimal filter (1) j=M, belonging to the aforementioned set of filters, is chosen, in such a way that said optimal filter (1) M comprises the combination of thicknesses {t_{iM}} that maximises the merit function Ef_{total M} for a given number L of layers (2), out of all the merit functions calculated in the preceding step.

The multilayer filter (1) method of configuration is therefore capable of quantifying the merit function until the optimal filter (1) for a defined number L of layers (2) is found.

### 4.—Optimising the Number of Layers (2)

The method of the invention may include a final step in which an optimal filter (1) is calculated for several amounts of different layers; that is, by varying the parameter L, to then choose one of said optimal filters (1).

For this, a secondary set, s={L₁, . . . Lₛ}, of initial filters is defined, each one of those filters with a number Lₛ of layers (2) different from each other, as well as different from the number L of layers (2) of the first initial filter j, with known refractive indices and with a random thickness of each layer (2):

s={s}={L₁, . . . ,Lₛ} (Eq. 4.1)

tᵢⱼ={tᵢⱼ}={t₁ⱼ,t₂ⱼ, . . . ,t_{Ls j}} (Eq. 4.2)

Nᵢ={Nᵢ}={N₁,N₂, . . . ,N_{LS}} (Eq. 4.3)

Where i=1, . . . , Lₛ is the layer (2) in question and tᵢⱼ is the random initial thickness of layer (2), i, of the initial filter, j, now belonging to the set, s. Each layer (2) also has a complex refractive index, Nᵢ, known over a specified wavelength range.

The calculations in steps 2 and 3 are repeated for each of these initial filters, j, of the secondary set, s={L₁, . . . , Lₛ}, to obtain an optimal filter (1) of the secondary filter set for each number, Lₛ, of layers (2) given and these results are recorded.

Lastly, a final filter is chosen from the entire set of optimal filters (1), which meets other technical criteria, such as the amount of material available for its manufacture, the possible precision in the thickness of the layers at the time they are deposited or the desired minimum efficiency. Thus, not all optimal filters (1) have to be equally efficient for a different number of Lₛ layers. For example, an optimal filter (1) with Lₛ=20 layers can have high efficiency and an optimal filter (1) with Lₛ=5 layers can have an efficiency only a small percentage below the previous one. In this case, the optimal filter (1) with the least number of layers can be chosen as the final filter, due to its simplicity when manufacturing it. Alternatively, other selection criteria for a final filter can be established, depending on technical needs.

The method for configuring an optimal multilayer filter (1) that maximises the merit function defined in Eq. 2.12 described above, therefore deals with the resolution of a complex mathematical problem that includes fields of optics, semiconductors, solar PV and solar CSP power. The method of the invention provides a way to find highly efficient, technically and economically feasible solutions to configure a selective filter (1) for sunlight. Addressing this problem using conventional designs, applying the state-of-the-art quarter-wavelength theory, does not enable a solution to be reached that is as precise and efficient as with the method described in the preceding paragraphs.

According to the method of the invention, the light selective filter (1) will typically have an aperiodic design (given that a periodic design is not necessarily more efficient), formed by a pair of transparent high-low refractive index oxides, which solves the shortcomings in the state of the art and presents a series of advantages:
Being an aperiodic design, the number of layers (2) necessary for optimisation is greatly simplified, which results in simplicity and a very low manufacturing cost. FIG. 4 shows the reflectance curve and the transmittance curve for configuration of the filter (1) of only 7 layers, which improves efficiency, simplifies manufacturing and, additionally, reduces costs, given that less deposition on the substrate (3) and less material are needed.
It is a much more efficient design than heat-films or hot mirrors, given that it spectrally selects which wavelength range or ranges to transmit or reflect in order to maximise the joint efficiency of the system. The wavelength ranges of hot mirrors or heat reflective films are not adjusted to maximise the efficiency of the photovoltaic and solar thermal (PV+CSP) system.
The aperiodic design makes it possible to discern the areas of the solar spectrum in which the photovoltaic cell (4) receives radiation, being able to not reflect the radiation in infrared areas that do not receive solar radiation due to the absorption peaks of water vapour.
It allows for greater spectral sensitivity with fewer layers (2) when transmitting or reflecting light, which, again, has a better efficiency/cost ratio. As can be seen in FIG. 4, the reflectance/transmittance of these filters (1) differs from that of a heat film or hot-mirror. Firstly, the transmittance is very high, up to approximately 1,000 nm, given that up to that wavelength, the energy that would be obtained via a photovoltaic transformation is more efficient than solar thermal transformation. In addition, a very pronounced reflection peak of between 400-500 nm is observed, which gives it a very distinctive bluish tone with respect to a heat-film and which also maximises the total efficiency of the system given that, within these ranges, the photovoltaic cell (4) it is not very efficient.

Another aim of the invention relates to a multilayer filter (1) configured via the method described above. Preferably, the layers (2) comprising the filter (1) are a pair of transparent high-low refractive index oxides and can be deposited directly onto a glass of a photovoltaic module, more preferably on its internal side, so that it is protected from external conditions.

The characteristics of a selective multilayer solar radiation filter (1), apt to maximise the integrated efficiency of a PV-CSP plant according to a preferred embodiment of the invention, are generally described below:

In a preferred embodiment of the light selective filter (1) of the invention, said filter (1) is dichroic. With said dichroic filter (1), a differentiated treatment of sunlight according to wavelength is achieved, so that a fraction of the spectrum is selectively reflected, whilst the other fraction is transmitted through it; that is, it is an optical filter (1) used to selectively reflect or transmit light according to its wavelength. The cut-off wavelength is chosen at will according to need.

In general, the dichroic filter (1) comprises a stack of layers (2) of two transparent materials (in the visible or within a range of wavelengths) of different refractive index. The low index layer/high index layer assembly may have a periodic or aperiodic sequence, depending on the characteristics of the desired reflection and transmission spectra.

Even more preferably, the dichroic filter (1) of the invention is manufactured by sputtering techniques and its design will be defined by the following formula or expression:

Substrate/(a₁A)/(b₁B)/(a₂A)/(b₂B)/ . . . /(aₙA)/(bₙB) (Eq. 5.1)

Where the bar “/” represents an interface between layers (2), where A is the high index material and B is that of low refractive index and where aᵢ and bᵢ are the specific thicknesses of the layers (2). In the case of periodic designs, a₁=a₂= . . . =aₙ and b₁=b₂= . . . =bₙ, whilst in the case of aperiodic designs, the thicknesses will have different values, the latter being optimal for solar applications, given that they generate, not only interferential reflections caused by a periodic design, but also allow different reflections to be obtained in each layer and increase the number of combinations. This complexity may appear to be disadvantage a priori, although it is precisely what allows the filter (1) to be configured according to the desired requirements, by means of a powerful calculation tool.

In another preferred embodiment of the invention, the filter (1) is configured to allow the solar radiation of visible wavelengths to pass into the corresponding photovoltaic cell (4) and to reflect the solar radiation of wavelengths in the blue region and from 950-1,000 nm to the central receiver (5).

A spectral graph of the wavelengths reflected by the filter (1) of the invention is shown in FIG. 4, according to a preferred embodiment thereof.

More preferably, the dichroic filter (1) comprises layers of high/low refractive index transparent oxides (in a wavelength range like that of the visible range) laminated onto the photovoltaic cell (4). Said layers of transparent oxides are deposited on glass substrates by sputtering, which is ideally laminated on photovoltaic cells (3). Even more preferably, said oxides are silicon oxide as a low refractive index element and titanium oxide as a high refractive index element.

Even more preferably the thicknesses of both silicon oxide and titanium oxide will be between 5 and 500 nm.

The operation of the reflection and transmission of sunlight in a multilayer filter (1) like that of the invention, resembles that of FIG. 3, where a possible longitudinal section of an aperiodic filter (1) is shown under the transparent cover of a photovoltaic cell (4). In such a multilayer structure, the incident ray of light (100) undergoes reflection and refraction processes in all the interfaces (2′) that exist between the different layers (2) and between the last layer (2) and the inner air and the first layer (2) and the substrate (3) that configure the transparent cover, so that the reflected parts (102) in the different interfaces (2′) leave the filter (1) forming a reflected beam (101) in which, given that each reflected part (102) travels different optical paths, it has generated optical interference processes that remove certain ranges of wavelengths in the resulting reflected beam (101). This non-reflected wavelength range will precisely be the part of light transmitted (104) to the photovoltaic cell (4).

Preferably, the number of layers (2) is from 1 to 20. More preferably, the number of layers (2) is from 3 to 10 and, even more preferably, from 5 to 7.

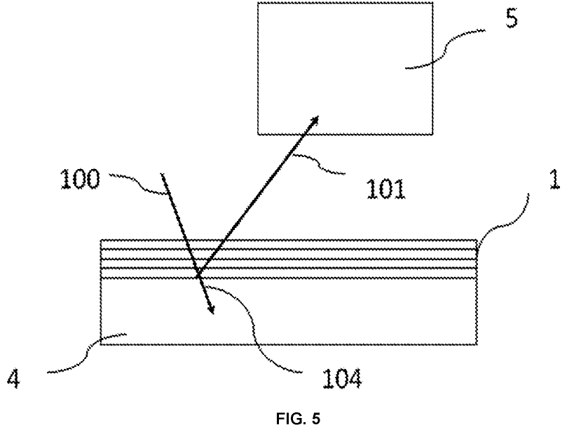

Another aim of the invention (FIG. 5) refers to the inclusion of this type of filters (1) in hybrid solar plants formed by modules or photovoltaic cells (4), which absorb part of the sunlight by injecting it into the network in the same way as a conventional photovoltaic plant; and, on the other hand, they reflect infrared rays and others within the visible spectrum to a central receiver solar thermal power plant (5) (PV-CSP solar power plant), which adds a new dimension to technology and solves the problems resulting from the current state of the art.

Therefore, as described, these filters (1) are designed with complex genetic algorithms that select the optimal combination of thicknesses for layers (2) from millions of possible combinations to maximise the sum of the efficiency in transforming the solar radiation within the photovoltaic range (the wavelength range where the silicon semiconductor typically absorbs photons to convert them into electrical energy) and the efficiency in transforming solar radiation within the concentrated solar thermal power range (PV+CSP).

None of the optimal solutions is based on a periodic design, which greatly limits the configuration options of the multilayer filter (1). In this way, the invention proposes a solution that overcomes the technical problems posed by providing an aperiodic ad-hoc filter (1) to selectively reflect and transmit sunlight. Additionally, many layers (2) are not necessary to find optimal solutions at the global PV+CSP performance level, which gives the product viability for solar applications at an industrial level due to the high efficiency achieved through the configuration obtained by the method of the invention. This type of solution is based on very powerful computing systems to optimise the described merit function, which moves away from the traditional design theory and methods for interferential filters, overcoming the difficulties of the state of the art.

1. A method for configuring a selective multilayer spectral-separation filter for solar radiation, suitable for placement on photovoltaic panels for use in power generation plants using solar energy, wherein the multilayer filter includes multiple layers of different refractive indices and thicknesses, the method comprising the following steps to configure said multilayer filter in terms of a desired transmittance and reflectance within a range wavelengths:
a) defining a first initial filter with a number of layers and refractive indices of known layers, with a random thickness of each layer;
b) calculating the transmittance and reflectance response of said initial filter within the desired wavelength range according to the optical admittance of the initial filter and the optical admittance of the medium;
c) calculating the photovoltaic efficiency of said initial filter according to the transmittance and reflectance calculated in step b) within the desired wavelength range, wherein:
the photovoltaic efficiency is calculated by multiplying the standard performance ratio of a photovoltaic plant by the efficiency of the photovoltaic cell according to its spectral response; and
the efficiency of the photovoltaic cell is defined in terms of the cell's current density, global radiation, the cell's open-circuit voltage and the fill factor;
d) calculating the thermal efficiency of said initial filter according to the transmittance and reflectance calculated in step b) within the desired wavelength range, wherein:
thermal efficiency is calculated by multiplying the average annual efficiency of a concentrated solar thermal power plant by the ratio of direct radiation versus direct radiation added to diffuse radiation, by the integrated reflectance of the initial filter for the desired wavelength range; and
the annual average efficiency of a concentrated solar power plant is calculated by multiplying the factors: solar field efficiency, cycle efficiency of turbine power and loss of plant efficiency due to equipment self-consumption;
e) calculating and recording a merit function, wherein the merit function is calculated as the sum of the photovoltaic and thermal efficiencies resulting from steps c) and d);
f) defining a set of initial filters with the same number of layers as the first initial filter but with different thicknesses for the layers of each of said filters with respect to the first initial filter and repeating steps b) to e) for each of said filters; and
g) selecting the optimal multilayer filter, belonging to the set of filters in stage f) plus the first initial filter, wherein said optimal multilayer filter comprises the combination of thicknesses that maximizes the merit function for a given number of layers, out of all of the merit functions calculated in step e).

2. The method of claim 1 for configuring a selective multilayer spectral-separation filter for solar radiation, further comprising:
defining a set of secondary filters, each with a different number of layers from each other, as well as with a different number of layers of the first initial filter, with known refractive indices and with a random thickness of each layer; and
repeating steps b) to g) to obtain an optimal multilayer filter of the secondary filter set for each given number of layers.

3. The method of claim 2 for configuring a selective multilayer spectral-separation filter for solar radiation, further comprising:
establishing a desired critical merit function;
establishing a desired critical number of layers; and
selecting a final optimal filter from amongst all of the registered optimal filters in such a way that said final optimal filter is that which is closest to the established criteria of said critical merit function and said critical number of layers.

4. The method of claim 1 for configuring a selective multilayer spectral-separation filter for solar radiation, wherein, in step b), the transmittance and reflectance response of said initial filter within the desired range of wavelengths is calculated by calculating at least the following parameters:
the characteristic matrix of a multilayer system;
the phase term according to the wavelength, the thickness of the layer and the angle of incidence;
the complex refractive index of a multilayer system;
the optical admittance of a substrate in which a multilayer deposition is carried out to build the multilayer filter.

5. The method of claim 1 for configuring a selective multilayer spectral-separation filter for solar radiation, wherein, in the step c), the current density is calculated from the wavelength and of the quantum efficiency of the cell.

6. A selective multilayer spectral-separation filter for solar radiation, suitable for maximizing the efficiency of a photovoltaic and concentrated solar thermal power system, configured via a method of configuration according to claim 1, comprising layers in aperiodic structure.

7. The multilayer filter of claim 6, further comprising transparent oxides of high and low refractive index.

8. The multilayer filter of claim 7, comprising titanium oxide and silicon oxide or any compound derived therefrom.

9. The multilayer filter of claim 8, wherein the silicon oxide and titanium oxide layers have thicknesses of between 5 and 500 nm.

10. The multilayer filter of claim 6, wherein the wavelength ranges with minimum reflection in said aperiodic structure correspond to wavelength ranges with maximum absorption within the terrestrial solar spectrum.

11. The multilayer filter of claim 6, further comprising a glass substrate.

12. The multilayer filter of claim 11, wherein the deposition of the layers on the glass substrate is carried out by means of the sputtering technique.

13. The multilayer filter of claim 6, wherein the layers include a number of layers of between 3 and 20.

14. The multilayer filter of claim 13, wherein the layers include a number of layers of between 3 and 10.

15. A power generation plant that is capable of harnessing solar energy, the power generation plant being configured for:
using at least one multilayer filter configured via a method of configuration according to claim 1, wherein the at least one multilayer filter is configured to allow solar radiation of visible wavelengths to pass into a corresponding photovoltaic cell and to reflect solar radiation of shorter and longer wavelengths with respect to visible radiation towards a central receiver.

16. The multilayer filter of claim 14, wherein the layers include a number of layers of between 5 and 7.

17. The method of claim 2 for configuring a selective multilayer spectral-separation filter for solar radiation, wherein, in step b), the transmittance and reflectance response of said initial filter within the desired range of wavelengths is calculated by calculating at least the following parameters:
the characteristic matrix of a multilayer system;
the phase term according to the wavelength, the thickness of the layer and the angle of incidence;
the complex refractive index of a multilayer system; and
the optical admittance of a substrate in which a multilayer deposition is carried out to build the multilayer filter.

18. The method of claim 3 for configuring a selective multilayer spectral-separation filter for solar radiation, wherein, in step b), the transmittance and reflectance response of said initial filter within the desired range of wavelengths is calculated by calculating at least the following parameters:
the characteristic matrix of a multilayer system;
the phase term according to the wavelength, the thickness of the layer and the angle of incidence;
the complex refractive index of a multilayer system; and
the optical admittance of a substrate in which a multilayer deposition is carried out to build the multilayer filter.

19. A selective multilayer spectral-separation filter for solar radiation, suitable for maximizing the efficiency of a photovoltaic and concentrated solar thermal power system, configured via a method of configuration according to claim 2, comprising layers in aperiodic structure.

20. A selective multilayer spectral-separation filter for solar radiation, suitable for maximizing the efficiency of a photovoltaic and concentrated solar thermal power system, configured via a method of configuration according to claim 3, comprising layers in aperiodic structure.
